(19) United States
(12) Patent Application Publication
(10) Pub. No.: US 2026/0182343 A1
(43) Pub. Date: Jun. 25, 2026

(54) LAYOUT OF SEMICONDUCTOR DEVICE AND METHOD OF MANUFACTURING THE SAME

(71) Applicant: TAIWAN SEMICONDUCTOR MANUFACTURING COMPANY LTD., HSINCHU (TW)

(72) Inventors: LI-WEI LU, TAICHUNG CITY (TW); SHANG-HSUAN CHIU, HSINCHU (TW); YU-CHIN HUANG, TAIPEI CITY (TW); YU-LUNG TUNG, KAOHSIUNG CITY (TW); YU-CHENG YEH, NEW TAIPEI CITY (TW)

(21) Appl. No.: 18/991,775

(22) Filed: Dec. 23, 2024

(51) Int. Cl. H01L 23/528; H01L 21/768

(52) U.S. Cl. CPC H10W 20/43; H10W 20/031

(57) ABSTRACT

A layout of a semiconductor device and method of manufacturing the same are provided. The layout includes a first cell. The first cell includes an active region pattern extending along a first direction. The first cell also includes a plurality of frontside first-layer signal line patterns, each extending along the first direction. The first cell further includes a plurality of frontside second-layer signal line patterns, each extending along a second direction different from the first direction. A first group of the frontside second-layer signal line patterns is offset from a second group of the frontside second-layer signal line patterns along the second direction.

### BACKGROUND

The semiconductor integrated circuit (IC) industry has experience rapid growth. In pursuit of higher device density, higher performance, and lower costs, technological advances in IC design have produced generations of ICs. Compared to previous generation, the present generation has smaller and more complex circuits. In IC evolution, the number of interconnected devices per chip area has generally increased while the smallest component or line that can be created using a fabrication process has decreased. This scaling-down process increases the complexity of designing and fabricating ICs.

### BRIEF DESCRIPTION OF THE DRAWINGS

Aspects of the embodiments of the present disclosure are best understood from the following detailed description when read with the accompanying figures. It should be noted that, in accordance with the standard practice in the industry, various structures are not drawn to scale. In fact, the dimensions of the various structures may be arbitrarily increased or reduced for clarity of discussion.

FIG. 1A illustrates a layout of a semiconductor device according to various aspects of the present disclosure.

FIG. 1B illustrates a layout of the frontside of a semiconductor device according to various aspects of the present disclosure.

FIG. 1C illustrates a layout of the backside of a semiconductor device according to various aspects of the present disclosure.

FIG. 2 illustrates a layout of a semiconductor device according to various aspects of the present disclosure.

FIG. 3 illustrates a layout of a semiconductor device according to various aspects of the present disclosure.

FIG. 4 illustrates a layout of a semiconductor device according to various aspects of the present disclosure.

FIG. 5 is a flowchart of a method for manufacturing a semiconductor device according to various aspects of the present disclosure.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, although terms such as “first,” “second” and “third” describe various elements, components, regions, layers and/or sections, these elements, components, regions, layers and/or sections should not be limited by these terms. These terms may only be used to distinguish one element, component, region, layer or section from another. Terms such as “first,” “second” and “third” when used herein do not imply a sequence or order unless clearly indicated by the context.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” and “about” generally mean within a value or range that can be contemplated by people having ordinary skill in the art. Alternatively, the terms “substantially,” “approximately” and “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of times, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should at least be construed in light of the number of reported significant digits and by applying ordinary rounding techniques. Ranges can be expressed herein as from one endpoint to another endpoint or between two endpoints. All ranges disclosed herein are inclusive of the endpoints, unless specified otherwise.

The present disclosure provides layouts 10a, 10b, 10c, and 10d. The layouts 10a to 10d provide regular patterns (or base cell layout). The regular patterns can be repeated along the X direction and the Y direction. The regular patterns can be implemented in function cells, engineering change order (ECO) cells, physical cells, filler cells, or another type of cells or combination of cells capable of being defined in an IC layout diagram after routing.

A function cell is a cell pre-designed to provide a specific function to an IC incorporating such a function cell. Examples of function cells include, but are not limited to, a logic gate cell, a memory cell, or the like. Examples of logic gate cells include, but are not limited to, AND, OR, NAND, NOR, XOR, INV, AND-OR-Invert (AOI), OR-AND-Invert (OAI), MUX, Flip-flop, BUFF, Latch, delay, clock, or the like. Examples of memory cells include, but are not limited to, a static random access memory (SRAM), a dynamic RAM (DRAM), a resistive RAM (RRAM), a magnetoresistive RAM (MRAM), a read only memory (ROM) cell, or another type of cell capable of having multiple states representative of logical values.

An ECO cell is a cell pre-designed without a specific function, but is programmable to provide an intended function. For example, to design an IC, the pre-designed layouts of one or more function cells are read out from a standard cell library and placed into an initial IC layout. The IC layout also includes one or more ECO cells which are not yet connected or routed to the function cells. When the IC layout is to be revised, one or more of the already placed ECO cells are programed to provide an intended function and routed to the function cells. The programing of ECO cells involves modifications in one or more layers of the IC layout and/or masks for manufacturing the IC.

A physical cell is a cell configured to provide a function, other than a logic function, to an IC incorporating such physical cell. Examples of physical cells include, but are not limited to, a TAP cell, a DCAP cell, or the like. A TAP cell defines a region in a doped well where the doped well is coupled to a bias voltage, such as a power supply voltage. TAP cells are included in an IC layout diagram, e.g., to improve latch-up immunity of ICs manufactured in accordance with the IC layout diagram. A DCAP cell includes one or more decoupling capacitors (decap) between power buses or rails, e.g., as a charge reservoir to provide additional power in situations where there is a high demand for current from the power supply.

A purpose of filler cells is to fill an empty space in an IC layout diagram, for example, to satisfy one or more design rules, such as a minimum spacing between adjacent features. In some embodiments, a physical cell is placed as a filler cell. In at least one embodiment, a filler cell is a cell with no logical functionality that is not connected or routed to other cells in an IC layout diagram. Cells other than filler cells are referred to herein as “non-filler cells.”

Further, the layout as shown in the layouts 10a to 10d can be applied to a super power rail (SPR) technique. More specifically, the input pin and the output pin are routed from the frontside side of a semiconductor device, and the power lines are routed from the backside of a semiconductor device.

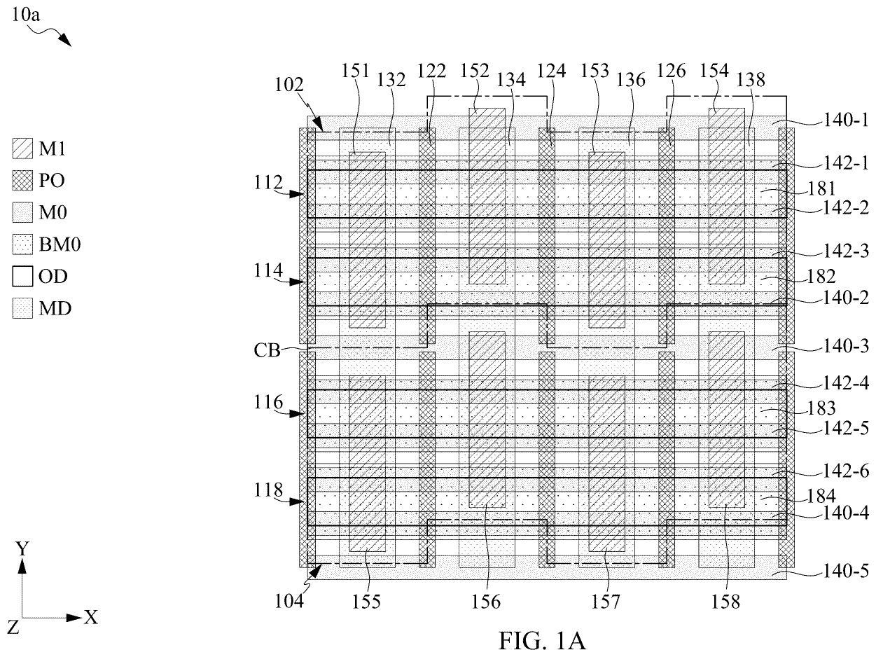

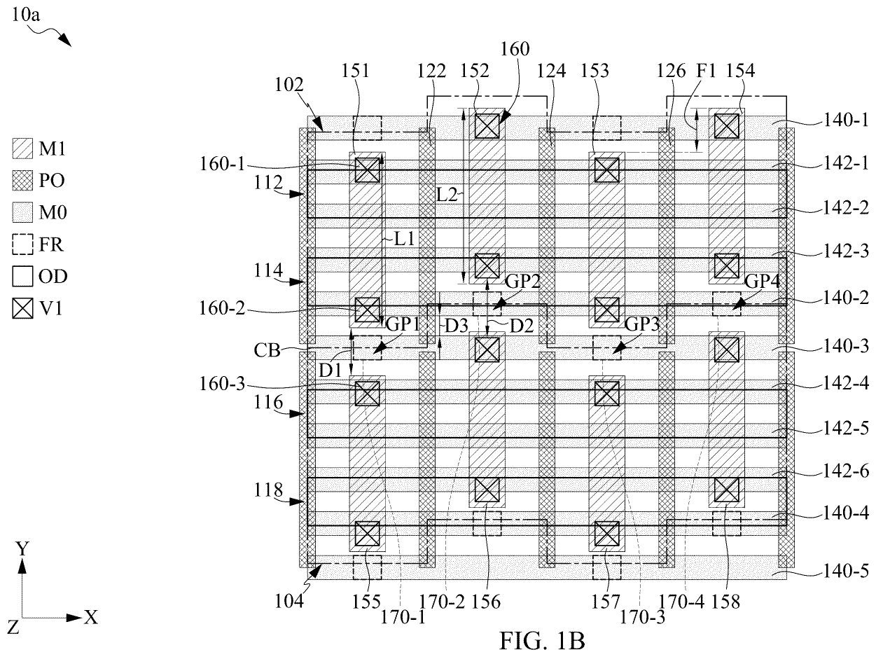

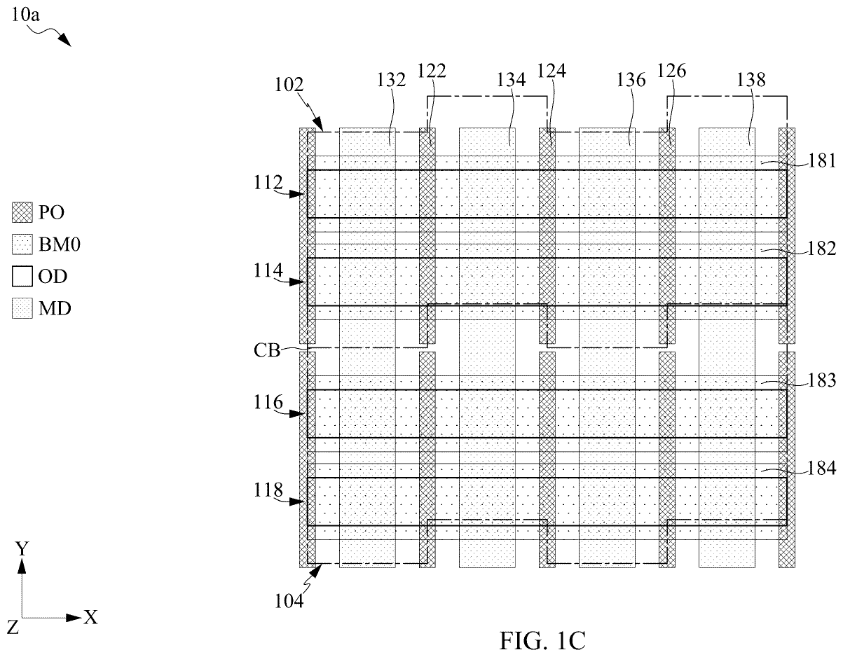

FIGS. 1A, 1B, and 1C illustrate a layout 10a of a semiconductor device according to various aspects of the present disclosure, wherein FIG. 1B illustrates the layout patterns of the frontside, and FIG. 1C illustrates the layout patterns of the backside of the layout 10a. In some embodiments, the layout 10a includes cells 102 and 104. The cell 104 abuts the cell 102 along the Y direction. In some embodiments, the layout 10a can include more cells repeated along the X direction and/or the Y direction.

Refer to FIGS. 1A and 1B, the layout 10a includes active region patterns 112, 114, 116, and 118. Each of the active region patterns 112 to 118 extends along the X direction. The active region patterns 112 and 114 are within the cell 102. The active region patterns 116 and 118 are within the cell 104. In some embodiments, each of the active region patterns 112 to 118 includes one or more fin structures for forming, for example, a fin field-effect transistor (FinFET). In some other embodiments, each of the active region patterns 112 to 118 may include one or more nanosheet structures. Each of the active region patterns 112 to 118 may correspond to an oxide definition layer (also referred to as “OD”) of a semiconductor device. Depending on requirements of the design, each of the active region patterns 112 to 118 may correspond to an active region of an n-type metal oxide semiconductor field effect transistor (NMOS) device or a p-type metal oxide semiconductor field effect transistor (PMOS) device.

In some embodiments, the layout 10a includes gate patterns 122, 124, and 126. Each of the gate patterns 122 to 126 extends along the Y direction and can correspond to a gate structure (or gate stack) of a semiconductor device. For example, the gate structure includes a gate dielectric and a gate electrode on the gate dielectric. The gate dielectric may include silicon oxide, silicon nitride, silicon oxynitride, high-k (dielectric constant greater than 4) dielectric layer, other dielectric material, or a combination thereof. The gate electrode may include polysilicon, silicon-germanium, and at least one metallic material including elements and compounds such as molybdenum, copper, tungsten, titanium, tantalum, titanium nitride, tantalum nitride, nickel silicide, cobalt silicide, or other suitable conductive materials. The gate patterns 122, 124, and 126 may also be referred to as “PO” in some embodiments.

In some embodiments, the layout 10a includes conductive feature patterns 132, 134, 136, and 138. Each of the conductive feature patterns 132 to 138 extends along the Y direction. In some embodiments, the conductive feature patterns 132 to 138 are arranged as source/drain (S/D) contacts that are electrically connected to the source regions and/or the drain regions. The S/D contact may include a conductive material, such as copper, titanium, tungsten, silver, aluminum, titanium aluminum alloy, titanium aluminum nitride, tantalum carbide, tantalum carbon nitride, tantalum silicon nitride, manganese, zirconium, titanium nitride, tungsten nitride, tantalum nitride, ruthenium, or a combination thereof. In some embodiments, the portion of the active region patterns 112 to 118 intersecting the conductive feature patterns 132 to 138 corresponds to source/drain features of a semiconductor device. In some embodiments, the conductive feature patterns 132 to 138 are also referred to as metal diffusion (MD) conductive features.

Although FIGS. 1A and 1C illustrate that one cell includes three POs and four MDs, it should be noted that the number of the POs and MDs are merely exemplary, and one cell can include any quantities of the POs and MDs. Further, the layout 10a can further include cutting features (not shown) for routing. For example, the layout 10a can further include a poly cut pattern (also referred to as “CPO”), which is configured to cut the PO. The layout 10a can further include dummy gate region patterns corresponding to a dummy gate of a semiconductor device. In some embodiments, the dummy gate region pattern corresponds to a non-functional conductive structure or a non-functional insulative structure of a semiconductor device. In some embodiments, the dummy gate region pattern corresponds to a cut poly on OD edge layer (also referred to as “CPODE”) of a semiconductor device. The layout 10a can further include an S/D contact cut pattern (also referred to as “CMD”), which is configured to cut or disconnect the MD.

In some embodiments, the layout 10a includes signal line patterns (or conducting lines or metal lines) 140-1, 140-2, 140-3, 140-4, and 140-5 as well as signal line patterns (or conducting lines or metal lines) 142-1, 142-2, 142-3, 142-4, 142-5, and 142-6. Each of the signal line patterns 140-1 to 140-5 and the signal line patterns 142-1 to 142-6 extends along the X direction. Each of the signal line patterns 140-1 to 140-5 and/or the signal line patterns 142-1 to 142-6 may be disposed over the active region patterns 112 to 118. Each of the signal line patterns 140-1 to 140-5 and/or the signal line patterns 142-1 to 142-6 may be disposed over or intersect the gate patterns 122 to 126 and/or the conductive feature patterns 132 to 138. Each of the signal line patterns 140-1 to 140-5 and/or the signal line patterns 142-1 to 142-6 can correspond to a metal zero (M0) layer of a semiconductor device. Each of the signal line patterns 140-1 to 140-5 and/or the signal line patterns 142-1 to 142-6 may be configured to be electrically connected to the PO and/or MD. It should be noted that the layout 10a can include interconnection patterns (not shown) for routing, which are configured to connect the M0 layer and PO (e.g., the via referred to as “VG”) and/or connect the M0 layer and MD (e.g., the via referred to as “VD”).

In some embodiments, the layout 10a includes signal line patterns (or conducting lines or metal lines) 151, 153, 155, and 157 as well as signal line patterns (or conducting lines or metal lines) 152, 154, 156, and 158. Each of the signal line patterns 151, 153, 155, and 157 as well as signal line patterns 152, 154, 156, and 158 extends along the Y direction. The signal line patterns 151 to 154 are disposed within the cell 102. The signal line patterns 155 to 158 are disposed within the cell 104. The signal line patterns 151 to 154 are arranged along the X direction. The signal line patterns 155 to 158 are arranged along the X direction. The signal line pattern 151 is substantially aligned with the signal line pattern 155 along the Y direction, and signal line pattern 152 is substantially aligned with the signal line pattern 156 along the Y direction.

Each of the signal line patterns 151 to 158 are disposed over and/or intersect some of the signal line patterns 140-1 to 140-5 and/or the signal line patterns 142-1 to 142-6. Each of the signal line patterns 151 to 158 can correspond to a metal first (M1) layer of a semiconductor device, which is located at an elevation or height, with respect to the active region, higher than that of the M0 layer. Each of the signal line patterns 151 to 158 may be configured to be electrically connected to the PO and/or MD. In some embodiments, the signal line patterns 140-1 to 140-5 and/or the signal line patterns 142-1 to 142-6 may be referred to as a first-layer signal line pattern, and the signal line patterns 151 to 158 may be referred to as a second-layer signal line pattern.

In some embodiments, the signal line patterns 151 to 154 are arranged along a stagger manner. In some embodiments, the signal line patterns 155 to 158 are arranged along a stagger manner. In some embodiments, the first group and the second group are arranged in a stagger manner along the X direction.

In some embodiments, the signal line patterns 151, 153, 155, and 157 are referred to as the first group of the M1 layers, and the signal line patterns 152, 154, 156, and 158 are referred to as the second group of the M1 layers. In some embodiments, the first group is offset from the second group along the Y direction within the same cell. For example, the signal line patterns 151 and 153 are offset from the signal line patterns 152 and 154 of the cell 102; the signal line patterns 155 and 157 are offset from the signal line patterns 156 and 158 of the cell 104. In some embodiments, the first group is offset from the second group by a distance D1, which may indicate the distance between two abutting M1 layers along the Y direction.

In some embodiments, at least a portion of one of the first group of the M1 layers is free from overlapping the second group of the M1 layers along the X direction. For example, a portion of the signal line pattern 151, which overlaps the signal line 140-2 along the Z direction, is free from overlapping the signal line patterns 152 and 154 along the X direction; a portion of the signal line pattern 152, which overlaps the signal line 140-1 along the Z direction, is free from overlapping the signal line patterns 151 and 153 along the X direction.

The M1 layers of abutting cells define gaps along the Y direction. For example, the signal line pattern 151 of the cell 102 and the signal line pattern 155 of the cell 104 define a gap GP1; the signal line pattern 152 of the cell 102 and the signal line pattern 156 of the cell 104 define a gap GP2; the signal line pattern 153 of the cell 102 and the signal line pattern 157 of the cell 104 define a gap GP3; the signal line pattern 154 of the cell 102 and the signal line pattern 158 of the cell 104 define a gap GP4. In some embodiments, the gaps GP1, GP2, GP3, and GP4 are arranged in a stagger manner along the X direction. For example, the gap GP1 is substantially aligned with the gap GP2 along the X direction and misaligned with the gaps GP3 and GP4 along the X direction. The gaps GP1 and GP3 are offset from the gaps GP2 and GP4 by the distance D1. In some embodiments, the dimensions (e.g., length) of the gaps GP1 to GP4 are substantially the same. In some embodiments, a portion of the M0 layers is exposed by the gaps of M1 layers. In some embodiments, a portion of the signal line pattern 140-2 is exposed by the gaps GP1 to GP4. For example, the signal line pattern 140-2 is exposed by the gaps GP2 and GP4. The signal line pattern 140-3 is exposed by the gaps GP1 and GP3. In this embodiment, two of the M0 layers (e.g., the signal line pattern 140-2 and signal line pattern 140-3) can be exposed by the gaps of the M1 layers between the cell 102 and the cell 104.

In some embodiments, the cell boundary (or boundary) CB of the cells 102 and 104 may be defined by the M1 layers. In some embodiments, the cell boundary (or boundary) CB of the cells 102 and 104 may have a zipper-shaped profile. In some embodiments, the cell boundary CB between the cells 102 and 104 passes through two of the M0 layers. For example, the cell boundary CB passes through the signal line pattern 140-2 and signal line pattern 140-3. In some embodiments, the cell boundary CB passes through the signal line pattern 140-2 and signal line pattern 140-3 alternatively. The signal line pattern 140-2 is shared by the cells 102 and 104. The signal line pattern 140-3 is shared by the cells 102 and 104. In some embodiment, the signal line patterns 140-1 to 140-5 may have at least a portion at the cell boundary CB or passed by the cell boundary CB. In some embodiment, the signal line patterns 142-1 to 142-6 are free from being passed by the cell boundary CB. In this embodiment, the region of the signal line patterns 140-1 to 140-5 that at the cell boundary can be defined as the M0 of the cell 102 and/or the M0 of the cell 104.

The first group of the M1 layers has a dimension (e.g., length) L1 along the Y direction. The second group of the M1 layers has a dimension (e.g., length) L2 along the Y direction. In some embodiments, the length L1 of the first group of the M1 layers is substantially the same as the length L2 of the second group of the M1 layers along the Y direction. For example, the length of the signal line pattern 151 is substantially the same as the length of the signal line pattern 152 along the Y direction.

In some embodiments, the layout 10a includes interconnection patterns (or interconnection features) 160. The interconnection patterns 160 may be configured to connect the M0 layer and M1 layer. For example, the interconnection patterns 160 can correspond to conductive vias between the M0 layers and M1 layers of a semiconductor device. The interconnection patterns 160 overlaps the M0 layers and M1 layers along the Z direction. The interconnection patterns 160 can be referred to as “V1.” In some embodiment, the interconnection patterns 160 are arranged in a stagger manner.

In some embodiments, the layout 10a includes forbidden patterns 170-1, 170-2, 170-3, and 170-4. In some embodiments, the forbidden patterns 170-1 to 170-4 overlaps the M0 layers along the Z direction. In some embodiments, the forbidden patterns 170-1 to 170-4 are free from overlapping the M1 layers along the Z direction. In some embodiments, each the forbidden patterns 170-1 to 170-4 represents a region or a portion that is not allowed for disposing an interconnection to connect the M0 layers and M1 layers. For example, the interconnection patterns 160 are disposed outside the forbidden patterns 170-1 to 170-4. The forbidden patterns 170-1 to 170-4 can be referred to as “FR” in this disclosure. In some embodiments, the cell boundary CB passes through the forbidden patterns 170-1 to 170-4. In some embodiments, a portion of the interconnection patterns 160 is aligned with the FR along the X direction.

The forbidden patterns 170-1, 170-2, 170-3, and 170-4 are disposed within the gaps GP1, GP2, GP3, and GP4, respectively. For example, the forbidden pattern 170-1 is disposed within the gap GP1 and located between the signal line patterns 151 and 155. In some embodiments, the forbidden patterns 170-1 to 170-4 are arranged in a stagger manner. In some embodiments, the forbidden patterns 170-1 and 170-3 are offset from the forbidden patterns 170-2 and 170-4 along the Y direction. In some embodiments, the forbidden patterns 170-1 and 170-3 are offset from the forbidden patterns 170-2 and 170-4 along the Y direction by the distance D1. In some embodiments, the FR between the cells 102 and 104 overlaps two M0 layers. For example, the forbidden patterns 170-1 to 170-4 are disposed on the signal line patterns 140-2 and 140-3 alternatively.

Refer to FIGS. 1A and 1C, the layout 10a includes power line patterns 181, 182, 183, and 184. The power line patterns 181 and 182 are located within the cell 102. The power line patterns 183 and 184 are located within the cell 102. Each of the power line patterns 181 to 184 may be electrically connected to a logic high power supply or positive power supply (VDD) or a logic low power supply or negative power supply (VSS). In this embodiment, each the power line patterns 181 to 184 can be referred to as a backside conductive feature. Similarly, each the M0 layers and M1 layers can be referred to as a frontside feature. The power line patterns 181 to 184 can be referred to as a backside metal zero “BM0” layer of a semiconductor device. The layout 10a can further include interconnection patterns (not shown) between the MD and BM0 or between the PO and BM0, which can be referred to as a backside via “VB.” In this embodiment, power may be routed thorough the BM0 layers, and signals may be routed thorough the M0 layers and M1 layers. In this condition, all of the metal tracks at the frontside (e.g., the signal line patterns 140-1 to 140-5 as well as 142-1 to 142-6) can be selected to transmit a signal (e.g., an input signal and/or output signal).

It should be noted that the interconnection patterns 160 shown in FIG. 1B are candidates, which are potential locations, for placing the V1. Other regions that overlap the M0 layers and M1 layers and outside the FR can be selected to dispose the V1. For example, the interconnection patterns 160-1 connects the signal line pattern 142-1 and the signal line pattern 151 in this embodiment. In other embodiments, the interconnection patterns 160-1 can connect the signal line pattern 142-2 and the signal line pattern 151 or connect the signal line pattern 142-3 and the signal line pattern 151 in other embodiments. In some embodiments, the distance of abutting two V1 is greater than the distance of abutting two M0 layers along the Y direction due to the limitation of process equipment. In this condition, V1 cannot be disposed on two abutting M0 layers. For example, if the interconnection patterns 160-2 is selected as the V1, the region corresponding to the forbidden pattern 171 cannot be selected as another V1 for routing. In this condition, at least one M0 layer is located between two V1 along the Y direction. For example, the signal line pattern 140-3 is located between the interconnection patterns 160-2 and 160-3. The interconnection patterns 160-2 and 160-3 are two candidates that have a minimum distance between two V1 along the Y direction. In some embodiments, a distance D2 is greater than a distance D3, wherein the distance D2 is defined as the minimum distance between V1 of different cells along the Y direction, and the distance D3 is defined as the distance between two M0 layers along the Y direction.

In a comparative example, the M1 layers are arranged without offset, and the cell boundary continuously passes through only one metal track of two cells. For example, in a comparative example, the signal line patterns 140-1, 140-3, and 140-5 are selected as the metal tracks through which the cell boundary passes. In this condition, the signal line patterns 140-1, 140-3, and 140-5 cannot be routed. More specifically, the V1 cannot be disposed on the metal tracks corresponding to the signal line patterns 140-1, 140-3, and 140-5 of a comparative example. In the embodiments of the present disclosure, one half of the signal line patterns 140-1 to 140-5 can be configured for routing. For example, the regions of the signal line pattern 140-3 overlapping the signal line patterns 156 and 158 can be configured for routing. Further, the M0 layer corresponding to the FR can be chosen as potential locations for placing the “VD” to connect the M0 layers and the MD in some conditions. As a result, more metal tracks can be routed, increasing routing flexibility compared to similar examples.

Further, in this embodiment, the layout as shown in FIGS. 1A to 1C can be applied to other layers of signal line patterns. For example, the patterns of the M0 and M1 layers can be applied to M2 and M3 layer or other suitable layers.

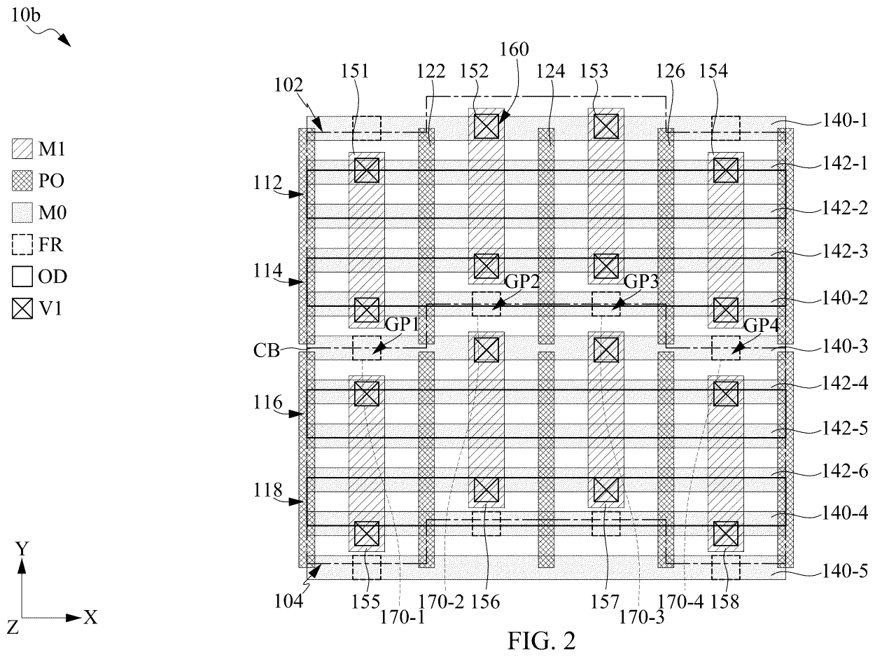

FIG. 2 illustrates a layout 10b of a semiconductor device according to various aspects of the present disclosure. The layout 10b has a layout similar to that of the layout 10a. One of the differences between the layouts 10b and 10a is that abutting two of the M1 layers may be aligned along the X direction. For example, the signal line pattern 153 is substantially aligned with the signal line pattern 152 and is offset from the signal line pattern 151. In some embodiments, the gap GP2 may be aligned with the gap GP3 along the X direction. In this embodiment, more metal tracks can be routed, increasing routing flexibility compared to similar examples.

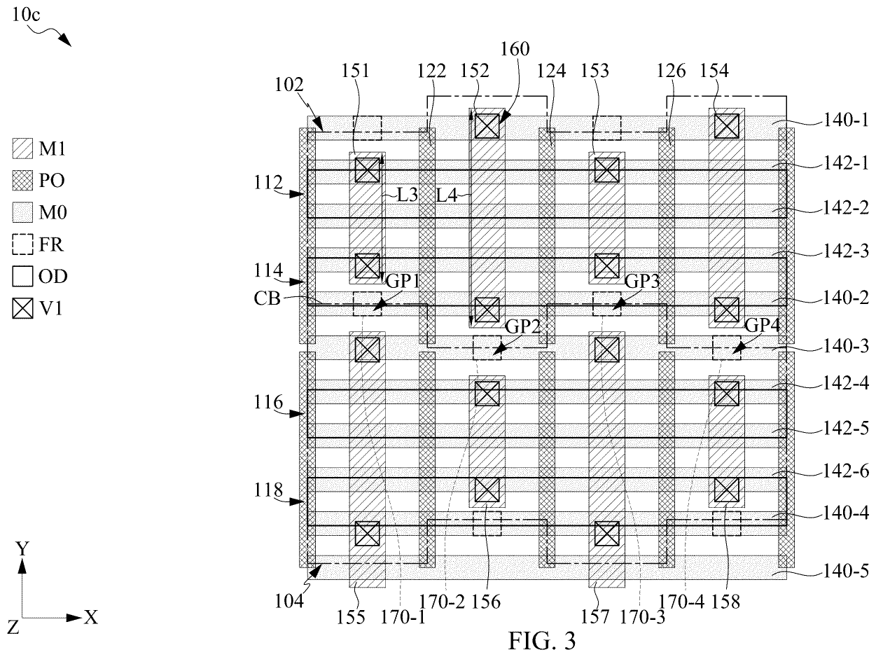

FIG. 3 illustrates a layout 10c of a semiconductor device according to various aspects of the present disclosure. The layout 10c has a layout similar to that of the layout 10a. One of the differences between the layouts 10c and 10a is that the M1 layers can have different dimensions (e.g., the length) along the Y direction. For example, the signal line pattern 151 has a dimension (e.g., length) L3 along the Y direction. The signal line pattern 152 has a dimension (e.g., length) L4 along the Y direction. In some embodiments, the dimension L4 is different from the dimension L3. In some embodiments, the ratio of the dimension L4 to the dimension L3 ranges between 1.4 and 2. Due to the varying dimensions of function cells, the signal line patterns 151 to 158 as shown in FIG. 3 can be utilized to integrate different function cells, as they may have different dimensions for different functions.

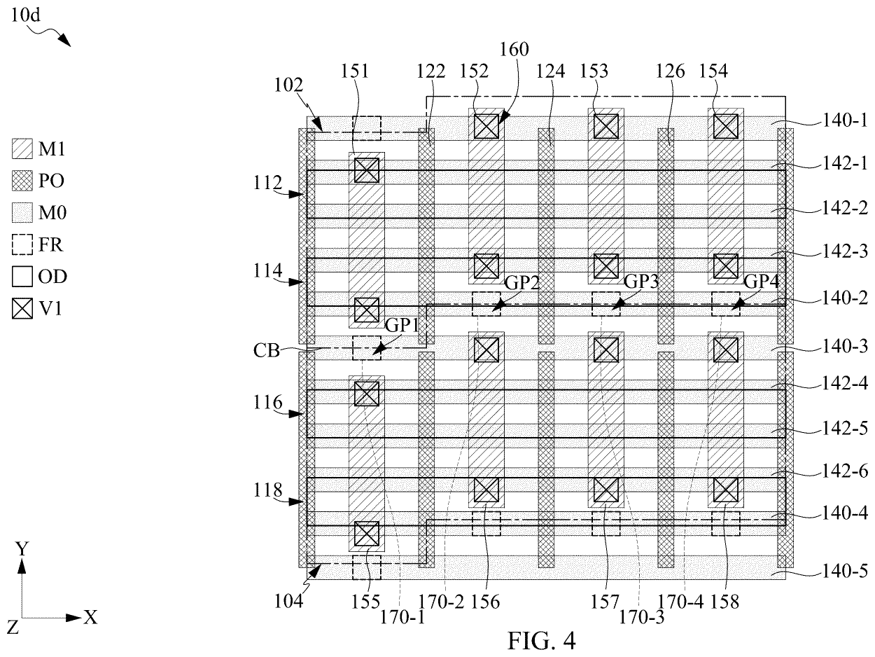

FIG. 4 illustrates a layout 10d of a semiconductor device according to various aspects of the present disclosure. The layout 10d has a layout similar to that of the layout 10a. One of the differences between the layouts 10d and 10a is that the signal line pattern 152 is substantially aligned with the signal line patterns 153 and 154 along the X direction. In some embodiments, the gaps GP2, GP3, and GP4 are aligned along the X direction and offset from the gap GP1 along the along the Y direction. In this embodiment, it is possible to configure 75% or more of the signal line pattern 140-3 to be routed with the V1. However, the present disclosure is not intended to be limiting. In other embodiments, 25% or less of the M0 layers can be configured for routing with the V1, depending on the dimension of the cell. In this embodiment, at least a portion of the signal line pattern 140-3 can be configured for routing. For example, between 20% and 80% of the M0 at the cell boundary can be configured for routing. Therefore, more metal tracks can be routed in comparison with comparative examples.

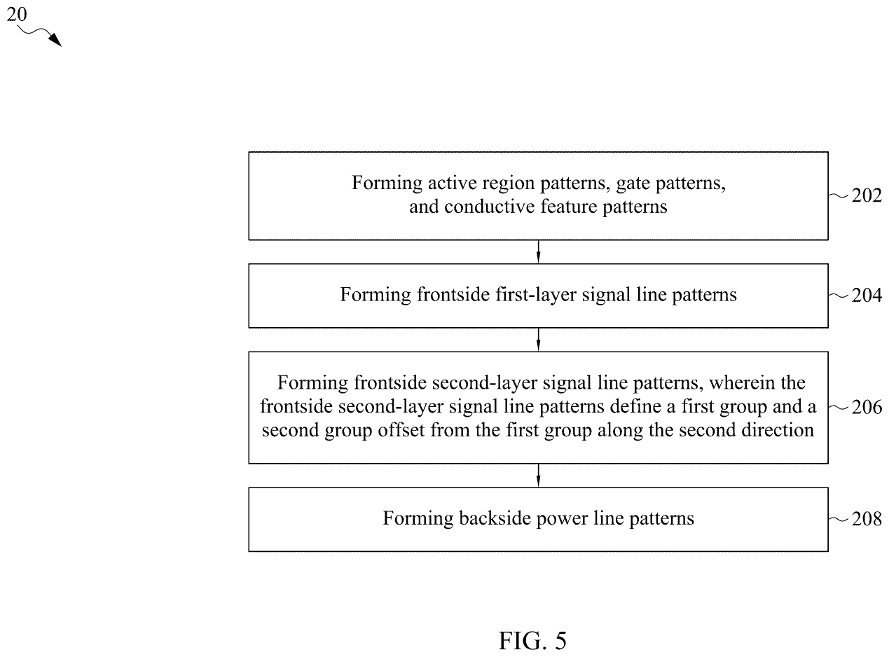

FIG. 5 is a flowchart of a method 20 for manufacturing a semiconductor device according to various aspects of the present disclosure.

The method 20 begins with an operation 202 in which active region patterns, gate patterns, and conductive feature patterns are formed. The active region patterns extend along a first direction. The gate patterns and conductive feature patterns extend along a second direction different from the first direction.

The method 20 continues with an operation 204 in which frontside first-layer signal line patterns are formed. The frontside first-layer signal line patterns extend along the first direction.

The method 20 continues with an operation 206 in which frontside second-layer signal line patterns are formed. The frontside second-layer signal line patterns define a first group and a second group offset from the first group along the second direction. For example, the gaps of the frontside second-layer signal line patterns are arranged in a stagger manner.

The method 20 continues with an operation 208 in which backside power line patterns are formed. The backside power line patterns extend along the first direction.

Some embodiments of the present disclosure provide a layout a semiconductor device. The layout includes a first cell. The first cell includes an active region pattern extending along a first direction. The first cell also includes a plurality of frontside first-layer signal line patterns, each extending along the first direction. The first cell further includes a plurality of frontside second-layer signal line patterns, each extending along a second direction different from the first direction. A first group of the frontside second-layer signal line patterns is offset from a second group of the frontside second-layer signal line patterns along the second direction.

Some embodiments of the present disclosure provide a layout of a semiconductor device. The layout includes a first cell and a second cell abutting the first cell along a first direction. The layout also includes a plurality of frontside first-layer signal line patterns in the first cell and the second cell, each extending along a second direction different from the first direction. The layout further includes a plurality of frontside second-layer signal line patterns in the first cell and the second cell, each extending along the first direction. The plurality of frontside second-layer signal line patterns define gaps, and the gaps are arranged in a stagger manner.

Some embodiments of the present disclosure provide a method of forming a layout a semiconductor device. The method includes: defining a first cell, including: forming an active region pattern which extends along a first direction; forming a plurality of frontside first-layer signal line patterns over the active region pattern, each extending along the first direction; and forming a plurality of frontside second-layer signal line patterns, each extending along a second direction different from the first direction, wherein a first group of the frontside second-layer signal line patterns is offset from a second group of the frontside second-layer signal line patterns along the second direction.

The foregoing outlines structures of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A layout of a semiconductor device, comprising:
a channel region extending along a first direction;
a plurality of frontside first conducting lines, each extending along the first direction; and
a plurality of frontside second conducting lines, each extending along a second direction different from the first direction,
wherein a first group of the frontside second conducting lines is offset from a second group of the frontside second conducting lines along the second direction.

2. The layout of claim 1, further comprising:
forbidden patterns overlapping the plurality of frontside first conducting lines along a third direction different from the first direction and the second direction, wherein the forbidden patterns are arranged in a stagger manner; and
interconnection features configured to connect one of the plurality of frontside first conducting lines and one of the plurality of frontside second conducting lines, wherein the interconnection features are outside the forbidden patterns.

3. The layout of claim 2, wherein the forbidden patterns are free from overlapping the plurality of frontside second conducting lines along the third direction.

4. The layout of claim 2, wherein a first distance between abutting two of the interconnection features is greater than a second distance between abutting two of the plurality of frontside second conducting lines along the second direction.

5. The layout of claim 1, wherein a first length of one of the first group of the plurality of frontside second conducting lines is the same as a second length of one of the second group of the plurality of frontside second conducting lines.

6. The layout of claim 1, wherein a first length of one of the first group of the plurality of frontside second conducting lines is different from a second length of one of the second group of the plurality of frontside second conducting lines.

7. The layout of claim 1, further comprising:
a plurality of backside power line patterns, each extending along the first direction.

8. The layout of claim 1, further comprising:
a first cell and a second cell abutting the first cell, each comprising the plurality of frontside first conducting lines and the plurality of frontside second conducting lines,
wherein a cell boundary between the first cell and the second cell is arranged in a stagger shape.

9. The layout of claim 8, wherein the cell boundary between the first cell and the second cell passes through two of the plurality of frontside first conducting lines.

10. A layout of a semiconductor device, comprising:
a first cell and a second cell;
a cell boundary between the first cell and the second cells, wherein the cell boundary is arranged in a stagger shape,
and wherein the first cell and the second cell share a same metal line, and at least one interconnect feature is located on the same metal line.

11. The layout of claim 10, further comprising:
a plurality of frontside first conducting lines including the same metal line, each extending along a first direction; and
a plurality of frontside second conducting lines, each extending along a second direction different from the first direction,
wherein the plurality of frontside second conducting lines define gaps, and at least one of the gaps exposes the same metal line.

12. The layout of claim 11, further comprising:
forbidden patterns overlapping the plurality of frontside first conducting lines along a third direction different from the first direction and the second direction, wherein the forbidden patterns are disposed within the gaps.

13. The layout of claim 12, wherein the forbidden patterns are free from overlapping the plurality of frontside second conducting lines along the third direction.

14. The layout of claim 11, wherein a first group of the frontside second conducting lines is offset from a second group of the frontside second conducting lines along the second direction.

15. The layout of claim 14, wherein a first length of one of the first group of the plurality of frontside second conducting lines is different from a second length of one of the second group of the plurality of frontside second conducting lines.

16. A method of forming a layout of a semiconductor device, comprising:
defining a first cell, comprising:
forming an active region pattern which extends along a first direction;
forming a plurality of frontside first-layer signal line patterns over the active region pattern, each extending along the first direction; and
forming a plurality of frontside second-layer signal line patterns, each extending along a second direction different from the first direction,
wherein a first group of the frontside second-layer signal line patterns is offset from a second group of the frontside second-layer signal line patterns along the second direction.

17. The method of claim 16, further comprising:
forming a plurality of backside power line patterns, each extending along the first direction.

18. The method of claim 16, further comprising:
forming interconnection patterns configured to connect one of the plurality of frontside first-layer signal line patterns and one of the plurality of frontside second-layer signal line patterns, and the interconnection patterns are arranged in a stagger manner.

19. The method of claim 18, further comprising:
defining a second cell abutting the first cell along the second direction,
wherein a cell boundary, defined by the plurality of frontside second-layer signal line patterns, between the first cell and the second cell has a zipper-shaped profile.

20. The method of claim 16, wherein one of the plurality of frontside first-layer signal line patterns within the first cell overlaps one half of the plurality of frontside second-layer signal line patterns within the first cell along a third direction different from the first direction and the second direction.
